(19) United States
(12) Patent Application Publication
(10) Pub. No.: US 2014/0096793 A1
(43) Pub. Date: Apr. 10, 2014

(54) UV TREATMENT OF POLISHED WAFERS

(71) Applicant: SunEdison, Inc., St. Peters, MO (US)

(72) Inventors: Sasha J. Kweskin, St. Louis, MO (US); Larry W. Shive, St. Charles, MO (US)

(21) Appl. No.: 14/045,325

(22) Filed: Oct. 3, 2013

Related U.S. Application Data
(60) Provisional application No. 61/709,651, filed on Oct. 4, 2012.

(51) Int. Cl. H01L 21/02

(52) U.S. Cl. CPC H01L 21/02054
USPC 134/1.3

(57) ABSTRACT

A method is provided for cleaning a surface of a semiconductor wafer comprising: (a) contacting the front surface of the wafer with a slurry comprising an abrasive agent and a polymeric rheological modifier; (b) contacting the front surface of the semiconductor wafer with an oxidant; and (c) irradiating the front surface of the semiconductor wafer with ultraviolet light.

### CROSS REFERENCE TO RELATED APPLICATION

This application claims priority from U.S. Provisional Application Ser. No. 61/709,651, filed Oct. 4, 2012, the disclosure of which is incorporated herein as if set forth in its entirety.

FIELD OF THE DISCLOSURE

The field of the invention relates generally to a method for cleaning semiconductor wafers and more particularly to a treatment for facilitating the cleaning of wafers post chemical mechanical polishing.

### BACKGROUND OF THE DISCLOSURE

Integrated circuits are fabricated in the surfaces of silicon wafers. The integrated circuits are located within discrete units identified as chips or dice. Each chip or die contains the devices and circuits which will constitute a discrete manufactured product. The dice are arranged on the wafer according to a wafer map to optimize the number of functional dice within each wafer.

Integrated circuit fabrication demands a planar, clean surface. Chemical mechanical polishing (CMP) for planarization enables the production of integrated circuits on flat wafer surfaces. CMP yields flat, consistent surfaces on which additional layers of interconnect structures and/or devices may be built. Polishing solutions consist of abrasive particles including salts, colloidal silica, alumina, silicon carbide etc., alkaline etchants, amine accelerants, polyether polyol, cellulosic stabilizers like hexaethyl cellulose. The removal of CMP slurries from the surface of the wafer after polishing represents a significant cleaning challenge. Defects from particles, stains and corrosion can change the electrical characteristics of a material and cause device failure. Accordingly, the polished wafers are subjected to a cleaning operation, such as the RCA clean.

The conventional RCA clean is a standard set of wafer cleaning steps which need to be performed before high temp processing steps (e.g., oxidation, diffusion, CVD) of silicon wafers. The RCA clean generally involves the following steps:

Removal of the organic contaminants (Organic Clean);

Removal of thin oxide layer (Oxide Strip); and

Removal of ionic contamination (Ionic Clean).

The wafers are prepared by soaking them in DI water, ozonated water, or hydrogen peroxide solutions. The first step (called SC-1, where SC stands for Standard Clean) for removing organic contaminants is performed with a 1:1:5 solution of NH₄OH (ammonium hydroxide)+H₂O₂ (hydrogen peroxide)+H₂O (water) at 75 or 80° C. typically for 10 minutes. This treatment results in the formation of a thin silicon dioxide layer (about 10 Angstrom) on the silicon surface, along with a certain degree of metallic contamination (notably Iron) that shall be removed in subsequent steps. This is followed by transferring the wafers into a DI water bath. The second step is a short immersion in a 1:50 solution of HF+H₂O at 25° C., in order to remove the thin oxide layer and some fraction of ionic contaminants. The third and last step (called SC-2) is performed with a 1:1:6 solution of HCl+H₂O₂+H₂O at 75 or 80° C. This treatment effectively removes the remaining traces of metallic (ionic) contaminants.

### BRIEF DESCRIPTION OF THE DISCLOSURE

The present invention is directed to a method for cleaning a surface of a semiconductor wafer, the semiconductor wafer comprising two major, generally parallel surfaces, one of which is a front surface of the substrate and the other of which is a back surface of the substrate, a circumferential edge joining the front and back surfaces, and a central plane between the front and back surfaces. The method comprises (a) contacting the front surface of the wafer with a slurry comprising an abrasive agent and a polymeric rheological modifier; (b) contacting the front surface of the semiconductor wafer with an oxidant; and (c) irradiating the front surface of the semiconductor wafer with ultraviolet light.

The present invention is still further directed to a method for cleaning a surface of a semiconductor wafer, the semiconductor wafer comprising two major, generally parallel surfaces, one of which is a front surface of the substrate and the other of which is a back surface of the substrate, a circumferential edge joining the front and back surfaces, and a central plane between the front and back surfaces. The method comprises (a) contacting the front surface of the wafer with a slurry comprising an abrasive agent and a polymeric rheological modifier; (b) irradiating the front surface of the semiconductor wafer with ultraviolet light; and (c) contacting the front surface of the semiconductor wafer with an oxidant irradiating the front surface of the semiconductor wafer with ultraviolet light.

### DETAILED DESCRIPTION OF THE EMBODIMENT(S) OF THE DISCLOSURE

The present invention is directed to a method for cleaning a surface of a semiconductor wafer. More particularly, the present invention is directed to a cleaning operation for cleaning the surface of a semiconductor wafer post chemical mechanical polishing. The encapsulating agents, generally organic polymers, used to stabilize slurry during polishing are tough and resistant to harsh environments. Polymer and slurry leftover from the chemical mechanical polish may form into particles on the wafer surface. In view thereof, after polishing, it is conventional to perform an extensive cleaning operation, e.g., the conventional RCA clean. The leftover organic residue from polishing is conventionally cleaned in acidic and oxidizing chemical solutions. The method of the present invention is directed to an improved cleaning process which more effectively removes organic residue and particulate matter from the surface of a polished semiconductor wafer than the conventional methods known in the art.

The semiconductor wafers cleaned according to the method of the present invention comprise two major, generally parallel surfaces, one of which is a front surface of the substrate and the other of which is a back surface of the substrate, a circumferential edge joining the front and back surfaces, a central axis perpendicular to the front and back surfaces, a radius, R, measured from the central axis to the circumferential edge, and a central plane between the front and back surfaces. The semiconductor wafer may comprise a material selected from the group consisting of silicon, silicon carbide, silicon germanium, silicon nitride, silicon dioxide, gallium arsenic, gallium nitride, indium phosphide, indium gallium arsenide, germanium, and combinations thereof. In particularly preferred embodiments, the semiconductor wafers are sliced from a single crystal silicon ingot grown in accordance with conventional Czochralski crystal growing methods. Such methods, as well as standard silicon slicing, lapping, etching, and polishing techniques are disclosed, for example, in F. Shimura, Semiconductor Silicon Crystal Technology, Academic Press, 1989, and Silicon Chemical Etching, (J. Grabmaier ed.) Springer-Verlag, N.Y., 1982 (incorporated herein by reference). A sliced, lapped, and etched wafer is generally sorted according to thickness and planarity.

According to the present invention, a semiconductor wafer is polished in a chemical-mechanical process that smooths uneven surfaces left by the lapping and etching process. During polishing, the front and/or back surfaces of the wafer are contacted with an aqueous slurry comprising an abrasive agent and a polymeric rheological modifier. In general, abrasive components of the polishing slurry comprise abrasive particles, e.g., colloidal silica, alumina, silicon carbide, diamond, boron carbide, tungsten carbide, titanium nitride, cesium oxide, etc. Polymeric rheological modifiers include polymers such as polyether polyol, pectin derivatives, polyacrylamide, polymethyacrylic acid, cellulosic stabilizers such as cellulose, modified cellulose derivatives, cellulose ethers, starch modified cellulose derivatives, cellulose ethers, starch derivatives, hydroxyethylcellulose, hydroxypropylcellulose, and hexaethyl cellulose. Alkaline etchants may be included such as salts of calcium, strontium, barium, magnesium, and zinc. The pH may be adjusted using hydroxides of potassium, sodium, and ammonium. The polishing solution may comprise a corrosion inhibitor (i.e., a film-forming agent), particularly a heterocyclic organic compound with at least one 5- or 6-member heterocyclic ring as the active functional group, including 1,2,3-triazole, 1,2,4-triazole, benzotriazole, benzimidazole, benzothiazole, and mixtures thereof. The polishing composition may comprise a chelating or complexing agent, e.g., carbonyl compounds (e.g., acetylacetonates, and the like), simple carboxylates (e.g., acetates, aryl carboxylates, and the like), carboxylates containing one or more hydroxyl groups (e.g., glycolates, lactates, gluconates, gallic acid and salts thereof, and the like), di-, tri-, and poly-carboxylates (e.g., oxalates, phthalates, citrates, succinates, tartrates, malates, edetates (e.g., dipotassium EDTA), mixtures thereof, and the like), carboxylates containing one or more sulfonic and/or phosphonic groups, and the like. Suitable chelating or complexing agents also can include, for example, di-, tri-, or polyalcohols (e.g., ethylene glycol, pyrocatechol, pyrogallol, tannic acid, and the like) and amine-containing compounds (e.g., ammonia, amino acids, amino alcohols, di-, tri-, and polyamines, such as ethylene diamine, and the like).

The various polymeric components, salts, abrasives, and the like in the chemical mechanical polishing composition may remain on the surface of a wafer, even after a rinse in high purity water. The organic residue is generally tough to remove and resistant to harsh environments. Ozone or SC-1 cleaning has been used to remove the organic materials, but this cleaning progress is slow to degrade the organic, polymeric residue from the polishing composition and results in higher haze/roughness. The method of the present invention effectively and rapidly removes organic residues from the surface of polished wafers, thereby improving wafer throughput and quality.

According to the method of the present invention, after chemical mechanical polishing, the wafers are rinsed in a solution, e.g., ultrahigh purity water or a cleaning solution. In some embodiments, the wafers are contacted with ultrahigh purity water saturated with gaseous oxidants, such as oxygen or ozone. Alternatively, the ultrahigh purity water may contain hydrogen peroxide at a concentration up to 20%, such as from about 0.5% to about 5% hydrogen peroxide, such as about 5%. Still other oxidants include potassium persulfate/periodate, urea, inorganic acids, ammonium cerium nitrate. In some embodiments, the wafers may be contacted with a cleaning solution that is saturated with oxidants, such as ozone, oxygen, or hydrogen peroxide. The rinse may be carried out by spraying the wafers, e.g., cone, fan, or spray rinses, or immersing the wafers in the rinse solution. In some embodiments, contact with the ultrahigh purity water rinse comprising oxidizing agents may occur by immersing the wafers into the solution for a duration up to about 300 minutes, such as up to about 120 minutes, preferably up to about 30 minutes, such as between about 1 minute and about 30 minutes, such as between about 2 minutes and about 20 minutes. In some embodiments, the wafers may be contacted with a cleaning solution that is saturated with ozone. The wafers may be contacted, e.g., in a holding tank, with an ozonated cleaning solution for up to about 120 minutes, such as up to about 60 minutes, preferably about 15 minutes.

In some embodiments, the wafer may be irradiated with ultraviolet light before, after, or simultaneously with cleaning in water or cleaning solution, such as an SC-1 solution. An SC-1 solution conventionally comprises ammonium hydroxide, hydrogen peroxide as an oxidant, and deionized water. The classic formulation comprises these components in a 1:1:5 ammonium hydroxide (28%):hydrogen peroxide (30%):water ratio. Alternatively, amines may be used, such as quaternary amines having the general structure NR₄OH wherein R comprises an alkyl or aryl group, including tetramethyl ammonium hydroxide, tetraethyl ammonium hydroxide. Alternative oxidants may be used, such as ozone, oxygen or peroxides. In some embodiments, the cleaning solution may comprise acidic fluorides, such as ammonium fluoride or hydrogen fluoride. In some embodiments, the cleaning solution may be a saturated ozone solution comprising hydrogen fluoride. The cleaning solution may further comprise surfactants, such as alkyl phenoxy polyethylene oxide, alkyl phenoxy polyglycidols, acetylenic alcohols, betaines, and fluorinated alkyl sulfonates. The cleaning may be carried out by spraying the wafers, e.g., cone, fan, or spray rinses, or immersing the wafers in the cleaning solution. The exposure time may range up to about 60 minutes, such as up to about 25 minutes.

Although the rinse in the solution (e.g., ultrahigh purity water or cleaning solution) comprising oxidant is effective to remove a majority of the polishing slurry materials, the rinse in ultrahigh purity water and/or cleaning solution may not be sufficient to remove all organic residues left on the surface of a semiconductor wafer resulting from the chemical-mechanical polish. Accordingly, the method of the present invention further includes a step of irradiating the wafer with ultraviolet light. The wafer may be irradiated before, after, or simultaneously with the above-described rinse in solution containing an oxidant. The wafer may be rinsed in a solution that may or may not contain an oxidant, which may be followed by a second rinse in ultrahigh purity water or cleaning solution containing an oxidant during which the wafer is irradiated. The method of the present invention therefore involves the steps of polishing a wafer with an abrasive slurry comprising an abrasive agent, such as silica particles, and a polymeric rheological modifier, such as hexaethyl cellulose, followed by an optional rinse in solution (e.g., ultrahigh purity water or cleaning solution) which may comprise an oxidant, wherein said rinse may occur simultaneous with irradiation with UV light or the irradiation may occur after contacting the wafer with the solution comprising an oxidant. In typical usage, these steps are carried out before a conventional industry clean, such as the SC1 clean.

Ultraviolet exposure of wafers coated with polishing slurry enhances chain scission of polymers, such as hexaethylcellulose, which has been observed to absorb UV light around 220 nm. The polymeric and surfactant components of the chemical mechanical polishing slurry absorb UV radiation and undergo photolytic and photo-oxidative reactions that result in degradation into more soluble lower molecular weight products. This degradation facilitates post polish cleaning The combination of irradiation with UV light and chemical oxidizing environments supports better particle performance and faster cleaning throughput. In general, the UV wavelengths appropriate for the method of the present invention range from about 100 nm to about 350 nm, such as from about 180 nm to about 280 nm, such as from about 220 nm to about 260 nm, which has been found to efficiently lower the molecular weight of polymers and leave reactive species that oxidize and/or dissolve easily. A UV lamp such as PL-L36W/TUV from Universal Light Source Inc. is well suited for the method of the present invention. Such a lamp has an effective exposure of ˜16 in. and 36 watts. The exposure time may vary from about 0.1 seconds to about 60 seconds, such as from about 1 second to about 20 seconds, or from about 1 second to about 5 seconds. As the wafers are subsequently exposed to ozonated water or hydrogen peroxide in cleaning solutions, the value of this chemical treatment may be enhanced. The combination of the two treatments, hydrogen peroxide and UV result in a high throughput and efficient process for the removal of organics.

After rinsing and/or cleaning with exposure to UV radiation, the wafers are processed in cleaning solutions, such as SC-1 and SC-2 or other cleaning solutions conventional in the art.

Having described the invention in detail, it will be apparent that modifications and variations are possible without departing from the scope of the invention defined in the appended claims.

### EXAMPLES

The following non-limiting examples are provided to further illustrate the present invention.

### Example 1

### Post Polish Treatment of 200 mm Wafers

A population of silicon wafers of 200 mm diameter were collected after chemical mechanical polishing. Each wafer was treatment post-polish according to the protocols set forth in the following Table 1.

TABLE 1
Treatment Protocols

| | | | | | | | | |
|---|---|---|---|---|---|---|---|---|
| Treatment | 1 | 2 | 3 | 4 | 5 | 6 | 7 | 8 |

| | | | | | | | |
|---|---|---|---|---|---|---|---|
| UV | | X | X | X | X | | |
| Peroxide | X | | X | | X | | X |
| Rinse | | | X | X | X | X | X |

Wafers were irradiated with UV radiation having a mixed spectrum source of 180 to 280 nm UV-C wavelength in a single wafer cleaner for a duration of 5 minutes. At a distance of 10 mm, the exposure was performed under normal pressure and air atmosphere.

The wafers were rinsed in a room temperature peroxide solution comprising of water and peroxide in a 5 w/w %. The immersion time was limited to 5 minutes.

Wafers were rinsed in ultrapure DI water. In an immersion setup, the wafers were rinsed in an overflow system for more than 5 minutes.

### Example 2

### Contact Angle Measurement of Treated 200 mm Wafers

The contact angle was measured using the Kernco Model 360 Contact Angle Meter. The contact angle measurements were taken at one location on each sample. Two measurements were taken at each drop, one measurement on either side of the drop. Table 2 provides the data for the all the measurements.

TABLE 2
Contact Angle Measurements.

| Sample | 1^{st} Reading | 2^{nd} Reading | Average |
|---|---|---|---|
| Slot 1 | 24° | 23° | 23.5° |
| Slot 2 | 24° | 24° | 24° |
| Slot 3 | 11° | 9° | 10° |
| Slot 4 | 10° | 9° | 9.5° |
| Slot 5 | 10° | 11° | 10.5° |
| Slot 6 | 7° | 6° | 6.5° |
| Slot 7 | 29° | 29° | 29° |
| Slot 8 | 25° | 26° | 25.5° |

After polish, the wafers are hydrophobic. This affects the particle performance by causing dewetting of the rinse water and subsequent drying marks. The UV radiation modifies the surface, making it more hydrophilic. The formation of SI-OH groups facilitates cleaning. Gaseous byproducts of hydrocarbon contamination are expected to evolve during treatment.

After a hydrogen peroxide rinse, the wafers demonstrated the effect of the treatment. A 30% reduction in organics was observed compared to a standard rinse with peroxide (1 ng/cm²).

This written description uses examples to disclose the invention, including the best mode, and also to enable any person skilled in the art to practice the invention, including making and using any devices or systems and performing any incorporated methods. The patentable scope of the invention is defined by the claims, and may include other examples that occur to those skilled in the art. Such other examples are intended to be within the scope of the claims if they have structural elements that do not differ from the literal language of the claims, or if they include equivalent structural elements with insubstantial differences from the literal languages of the claims.

What is claimed is:

1. A method for cleaning a surface of a semiconductor wafer, the semiconductor wafer comprising two major, generally parallel surfaces, one of which is a front surface of the substrate and the other of which is a back surface of the substrate, a circumferential edge joining the front and back surfaces, and a central plane between the front and back surfaces, the method comprising:
(a) contacting the front surface of the wafer with a slurry comprising an abrasive agent and a polymeric rheological modifier;
(b) contacting the front surface of the semiconductor wafer with an oxidant; and
(c) irradiating the front surface of the semiconductor wafer with ultraviolet light.

2. The method of claim 1 wherein steps (a), (b), and (c) are carried out in that order.

3. The method of claim 2 wherein the front surface of the wafer is rinsed with ultrapure water after step (a) and before steps (b) and (c).

4. The method of claim 1 wherein steps (b) and (c) occur simultaneously and after step (a).

5. The method of claim 4 wherein the front surface of the wafer is rinsed with ultrapure water after step (a) and before steps (b) and (c).

6. The method of claim 1 wherein steps (c) occurs before step (b) and both of steps (b) and (c) occur after step (a).

7. The method of claim 6 wherein the front surface of the wafer is rinsed with ultrapure water after step (a) and before steps (b) and (c).

8. The method of claim 1 wherein the front surface of the wafer is contacted with an aqueous composition during irradiation.

9. The method of claim 8 wherein the aqueous composition comprises an oxidant.

10. The method of claim 1 wherein the abrasive agent comprises colloidal silica particles.

11. The method of claim 1 wherein the polymeric rheological modifier comprises a polymer selected from the group consisting of polyether polyol, pectin derivatives, polyacrylamide, polymethyacrylic acid, cellulose, modified cellulose derivatives, cellulose ethers, starch modified cellulose derivatives, cellulose ethers, starch derivatives, hydroxyethylcellulose, hydroxypropylcellulose, hexaethyl cellulose, and combinations thereof.

12. The method of claim 1 wherein steps (b) and (c) degrade the polymeric rheological modifier into lower molecular weight products.

13. The method of claim 1 wherein the oxidant is selected from the group consisting of oxygen, ozone, hydrogen peroxide, and any combination thereof.

14. The method of claim 1 wherein the oxidant is an aqueous composition comprising 0.5 to 5% hydrogen peroxide.

15. The method of claim 1 wherein the oxidant is an aqueous composition saturated with oxygen.

16. The method of claim 1 wherein the ultraviolet light is in the wavelength range from 180 nm to 280 nm.

17. The method of claim 1 wherein the ultraviolet light is in the wavelength range from 220 nm to 260 nm.
